(19) United States
(12) Patent Application Publication
(10) Pub. No.: US 2025/0122022 A1
(43) Pub. Date: Apr. 17, 2025

(54) GRIPPING DEVICE AND TRANSPORT APPARATUS INCLUDING THE SAME

(71) Applicant: SEMES CO., LTD., Chungcheongnam-do (KR)

(72) Inventor: Dong Won YUN, Gyeonggi-do (KR)

(21) Appl. No.: 18/890,723

(22) Filed: Sep. 19, 2024

(30) Foreign Application Priority Data
Oct. 16, 2023 (KR) 10-2023-0137416

(51) Int. Cl. B65G 17/20; H01L 21/677

(52) U.S. Cl. CPC B65G 17/20; H01L 21/6773; H01L 21/67733

(57) ABSTRACT

A gripping device connected to a vehicle for transporting items to be transported in a semiconductor manufacturing plant, includes: a base unit provided on the vehicle to be movable up and down; and a hand unit provided on the base unit and having an adjustable spacing to either secure or release the items, wherein the hand unit includes: motors; a conversion module converting the rotational motion of the motors into linear motion; and grippers connected to the conversion module, with their spacing adjusted in conjunction with the conversion module.

### CROSS-REFERENCE TO RELATED APPLICATION

This application claims priority from Korean Patent Application No. 10-2023-0137416 filed on Oct. 16, 2023 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a gripping device and a transport apparatus including the same.

### 2. Description of the Related Art

To manufacture semiconductor devices, processes such as deposition, photolithography, and etching are performed, with the respective semiconductor processing devices within semiconductor manufacturing lines. Objects such as wafers, essential for such semiconductor fabrication processes, can be stored in containers like Front Opening Unified Pods (FOUPs) and delivered to each semiconductor processing device. After completing the semiconductor fabrication processes, the objects are returned to the containers from each semiconductor processing device, and these filled containers can then be externally transported.

These containers can be transported between manufacturing process facilities using conveying devices such as Overhead Hoist Transport (OHT) systems. For example, these conveying devices may include vehicles configured to travel on rails mounted on the ceiling of a clean room.

In semiconductor manufacturing lines, there is a requirement for transporting not only substrates and/or chips, but also various items such as tapes, which need to be carried in boxes. Therefore, improvements are needed to enable the use of existing equipment for transporting these items without requiring operators to manually lift the boxes.

### SUMMARY

Aspects of the present disclosure provide a gripping device and a transport apparatus including the same, which enables the transportation of various items using the transporting apparatus that is typically for transferring substrates.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a gripping device connected to a vehicle for transporting items to be transported in a semiconductor manufacturing plant, includes: a base unit provided on the vehicle to be movable up and down; and a hand unit provided on the base unit and having an adjustable spacing to either secure or release the items, wherein the hand unit includes: motors; a conversion module converting the rotational motion of the motors into linear motion; and grippers connected to the conversion module, with their spacing adjusted in conjunction with the conversion module.

According to another aspect of the present disclosure, a transport apparatus includes: a vehicle for transporting items to be transported in a semiconductor manufacturing plant; and the aforementioned gripping device.

According to another aspect of the present disclosure, a transport apparatus includes: multiple vehicles for transporting box-shaped items to be transported in a semiconductor manufacturing plant, the items including first target items, which are supported on a first stand and have first and second specifications, and second target items, which are supported on a second stand and have third and fourth specifications that are different from the first and second specifications; a base unit provided on the vehicles to be movable up and down, the base unit including a first plate, which is connected to one of the vehicles, and a second plate, which is connected to another one of the vehicles; and a hand unit for gripping or releasing the items, the hand unit provided on the base unit and having an adjustable spacing to either secure or release the items, wherein the hand unit includes: a first hand module for gripping or releasing the first target items, which includes first couplings into which the first protrusions fit, and a first sensor for detecting the first stand; and a second hand module for gripping or releasing the second target items, which includes second couplings that fit into the coupling grooves, the first hand module includes: a first motor including a first shaft having a first thread formed on its outer circumferential surface, and a first bracket that allows the first shaft to be rotatable and is fixed to the first plate; a first moving module including linear motion (LM) guiders provided on the first plate, first moving blocks provided to be slidable on the LM guiders, and a first connecting block provided with the first moving blocks at both ends and having a first through hole formed with a second thread on its inner circumferential surface that engages with the first thread, and bent toward the first motor; and a pair of first grippers connected to the first moving module and provided at its bottom with first support plates, which extend downwardly toward the first target items to contact lower surfaces of the first target items, and the second hand module includes: a second motor provided with a second shaft with a third thread formed on its outer circumferential surface; a second moving module including a second connecting block, which has a second through hole formed with a fourth thread engaging the third thread, moves linearly by receiving rotational force from the second motor, and is bent at both ends at an acute or obtuse angle with guide holes formed therein, and a pair of second moving blocks including cam followers that slide or pull along the guide holes, and whose spacing is adjustable in conjunction with the second connecting block; a pair of second grippers connected to the second moving module and including first bars having bent surfaces that oppose circumferential surfaces of the second target items and extension surfaces that extend downwardly from the bent surfaces, second support plates provided at lower ends of the first bars and extend toward the second target items to support lower surfaces of the second target items, and third support plates extending in a different direction from the bent surfaces of the first bars to oppose the circumferential surfaces of the second target items; and fixed blocks including first blocks connected to the second plate and contacting the second target items with the third specification, second blocks connected to the second plate and contacting the second target items with the fourth specification, and third sensors for detecting contact with the second target items.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 illustrates how a transport apparatus according to some embodiments of the present disclosure transports items;

FIG. 2 illustrates first target items transported by the transport apparatus according to some embodiments of the present disclosure;

FIG. 3 illustrates second target items transported by the transport apparatus according to some embodiments of the present disclosure;

FIG. 4 is a front view illustrating a state where a first hand module of a gripping device is raised in the transport apparatus according to some embodiments of the present disclosure;

FIG. 5 is a front view illustrating a state where the first hand module of the gripping device is lowered in the transport apparatus according to some embodiments of the present disclosure;

FIG. 6 is a front view illustrating a state where the first hand module of the gripping device grips items to be transported in the transport apparatus according to some embodiments of the present disclosure;

FIG. 7 is a perspective view illustrating a first hand module of a gripping device according to a first embodiment of the present disclosure;

FIG. 8 is a perspective view illustrating a state where the spacing in the first hand module of the gripping device according to the first embodiment of the present disclosure is widened;

FIG. 9 is a perspective view illustrating a state where the spacing in the first hand module of the gripping device according to the first embodiment of the present disclosure is narrowed so that the first hand module contacts the items to be transported;

FIG. 10 is a front view illustrating a second hand module of the gripping device according to some embodiments of the present disclosure;

FIG. 11 is a perspective view a state where the spacing in a second hand module of the gripping device according to the first embodiment of the present disclosure is widened; and

FIG. 12 is a perspective view illustrating a state where the spacing in the second hand module of the gripping device with according to the first embodiment of the present disclosure is narrowed to grip the items to be transported.

### DETAILED DESCRIPTION

The following detailed description provides preferred embodiments of the present disclosure with reference to the accompanying drawings. The advantages and features of the present disclosure, as well as the methods of achieving them, will become apparent by referring to the detailed embodiments described below in conjunction with the drawings. However, the present disclosure is not limited to the embodiments disclosed herein and can be implemented in various forms. The provided embodiments are intended to fully disclose the invention and to convey the complete scope of the invention to those skilled in the art. The invention is defined only by the scope of the claims. Throughout the specification, like reference numerals refer to like elements.

The terminology used in this specification is intended to describe embodiments and is not intended to limit the invention. In this specification, the singular includes the plural unless otherwise specifically stated. The terms “comprises” and/or “comprising,” as used herein, do not exclude the presence or addition of one or more other elements, steps, operations, and/or features.

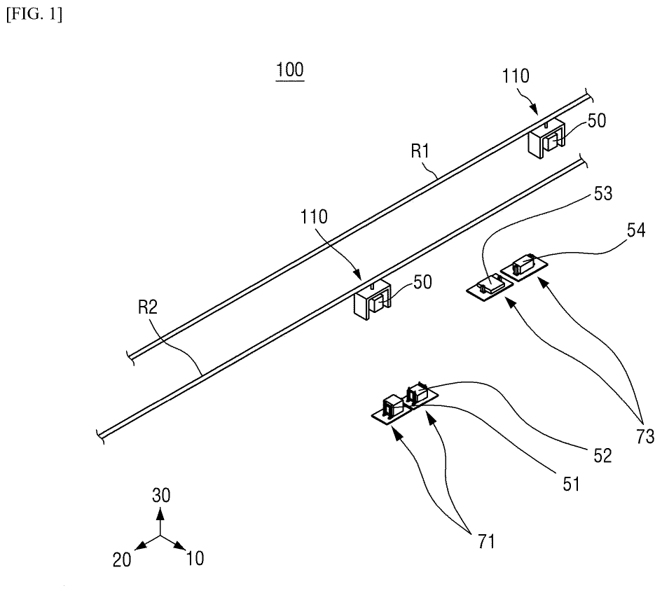

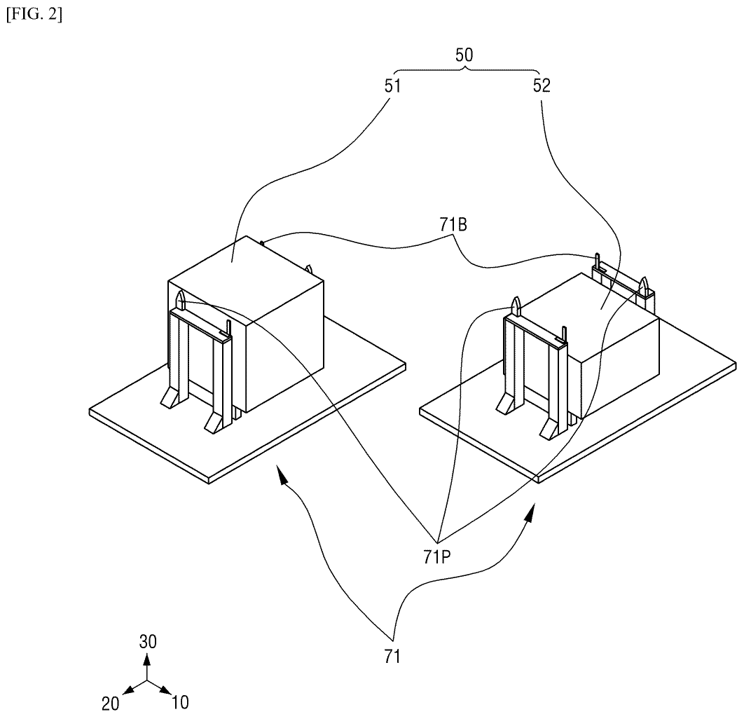

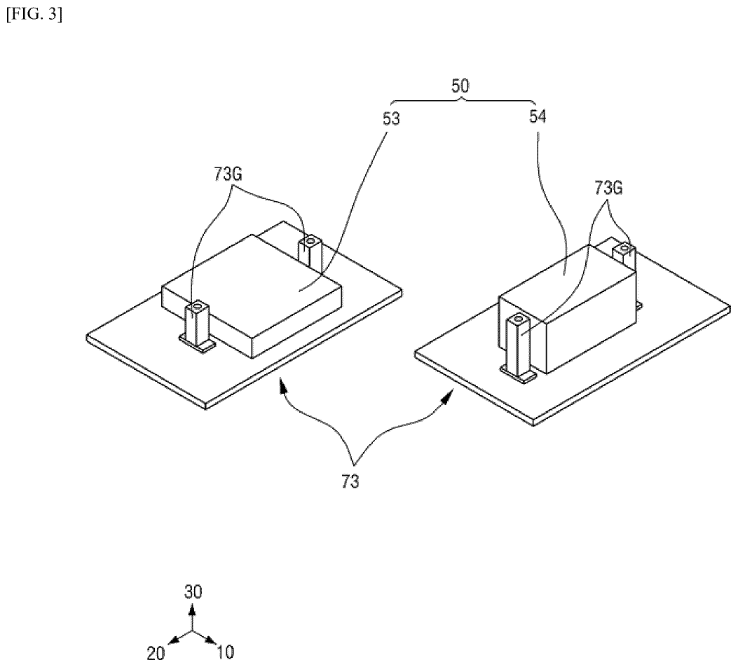

FIG. 1 illustrates how a transport apparatus according to some embodiments of the present disclosure transports items. FIG. 2 illustrates first target items transported by the transport apparatus according to some embodiments of the present disclosure, and FIG. 3 illustrates second target items transported by the transport apparatus according to some embodiments of the present disclosure.

Referring first to FIG. 1, a transport apparatus 100 may transport items 50 to be transported to target locations within a semiconductor manufacturing plant.

The target locations may be places within the semiconductor manufacturing plant that require various items, but the present disclosure is not limited thereto. There may be multiple target locations within the semiconductor manufacturing plant. A transport path may be provided to pass through the target locations within the semiconductor manufacturing plant.

The transport path may be defined by traveling rails R1 and R2, which are

connected to the ceiling. The places for loading the items 50 may be provided below the traveling rails R1 and R2. The traveling rails R1 and R2 include straight sections and curved sections.

The items 50 may be various types of boxes storing various articles, but the present disclosure is not limited thereto. The items 50 will hereinafter be described as being, for example, boxes.

Referring to FIGS. 2 and 3, the items 50 may include first target items 51 and 52 and second target items 53 and 54.

The first target items 51 and 52 and the second target items 53 and 54 may be boxes of two or more different types, but the present disclosure is not limited thereto. For example, the first target items 51 and 52 may have first and second specifications, and the second target items 53 and 54 may have third and fourth specifications. The first and second specifications may have, but are not limited to, a combined width, length, and height of 1000 mm to 1500 mm, and the third and fourth specifications may have, but are not limited to, a combined width, length, and height of 300 mm to less than 1000 mm.

Additionally, the first target items 51 and 52 may be heavier than the second target items 53 and 54. For example, the first target items 51 and 52 may weigh 10 kg to 25 kg, and the second target items 53 and 54 may weigh 3 kg to 9 kg. In this embodiment, the first, second, third, and fourth specifications may represent four types of boxes that differ in size and weight.

The first, second, third, and fourth specifications may sequentially decrease in size and weight in their order, but the present disclosure is not limited thereto.

Furthermore, as illustrated in FIG. 2, the first target items 51 and 52 may be supported by first pedestals 71, and as illustrated in FIG. 3, the second target items 53 and 54 may be supported by second pedestals 73. For example, each of the first pedestals 71 may be provided with first protrusions 71P and first sensor bars 71B, and each of the second pedestals 73 may be provided with coupling guiders 73G, which are formed with fitting grooves. However, the present disclosure is not limited to this example. Alternatively, the coupling guiders 73G may be formed on each of the first pedestals 71, or the first protrusions 71P and the first sensor bars 71B may be formed on each of the second pedestals 73.

The first target items 51 and 52 on the first pedestals 71 and the second target items 53 and 54 on the second pedestals 73 may be transported by the transport apparatus 100. The items 50 on the first pedestals 71 and the second pedestals 73 may be elevated from the surface of the floor, creating a gap therebelow, and thus, a hand unit (221 and 222) of the transport apparatus 100 may be inserted below the transported items 50 to be transported.

For example, the transport apparatus 100 may be provided as an Overhead Hoist Transport (OHT). The transport apparatus 100 may travel along the traveling rails R1 and R2 to transport the items 50 to the target locations. Accordingly, the transport apparatus 100 can transport the transported items 50 to be transported, which are provided as boxes, simply using an existing substrate transport system without the need for additional separate rails or moving devices.

The transport apparatus 100 will hereinafter be described with reference to the accompanying drawings.

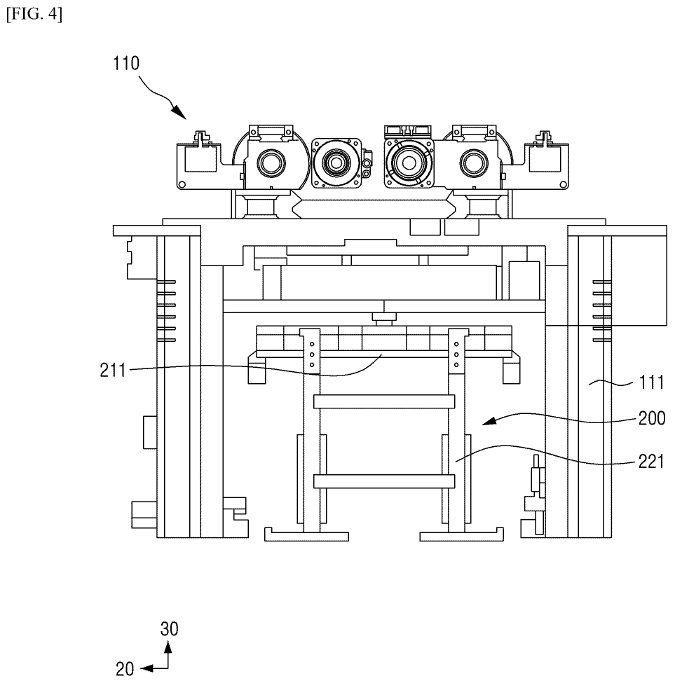

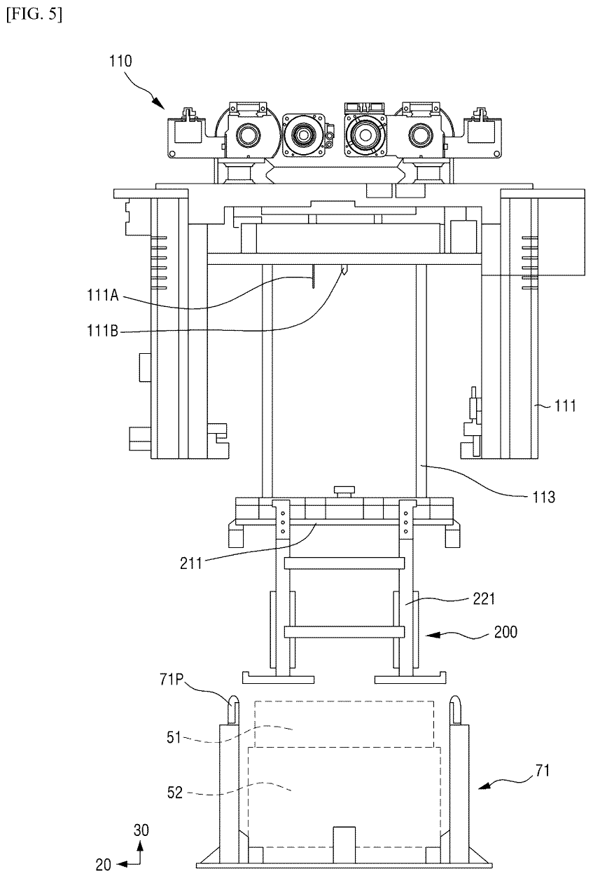

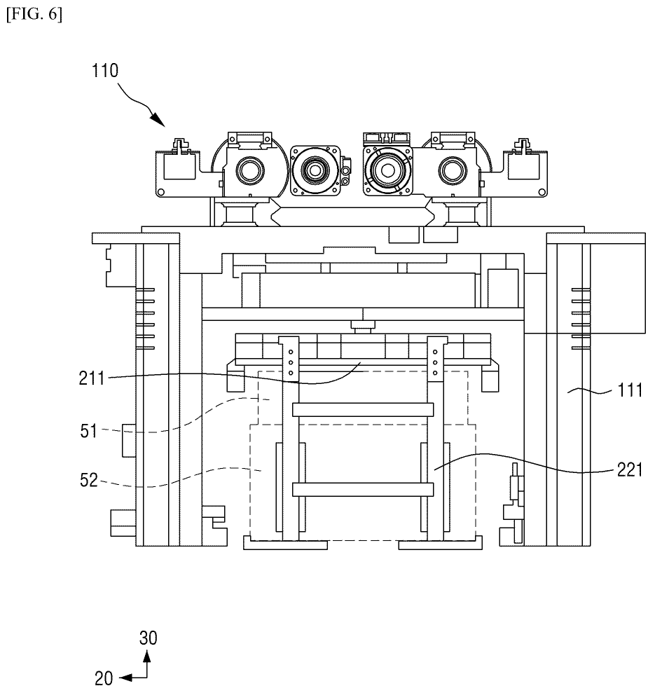

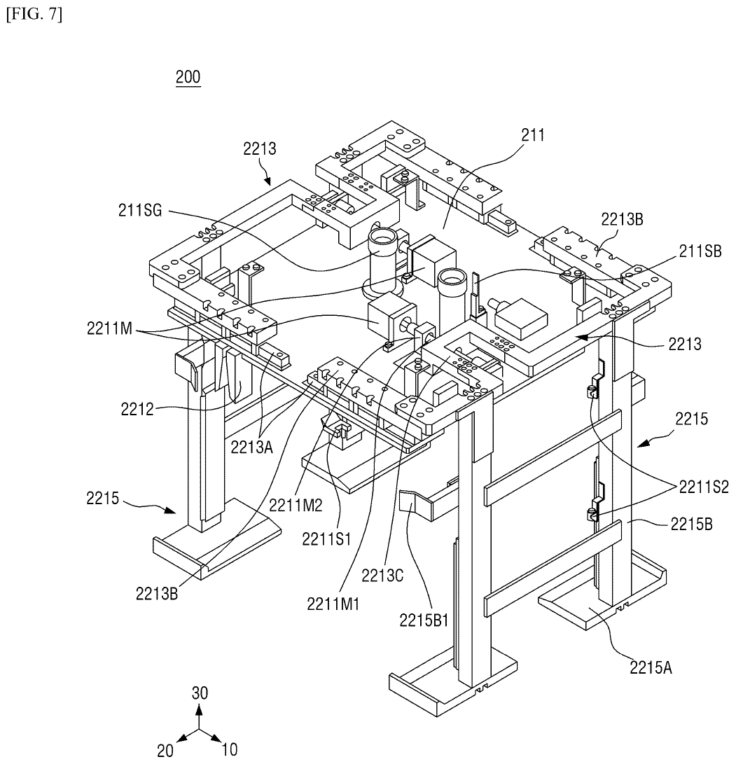

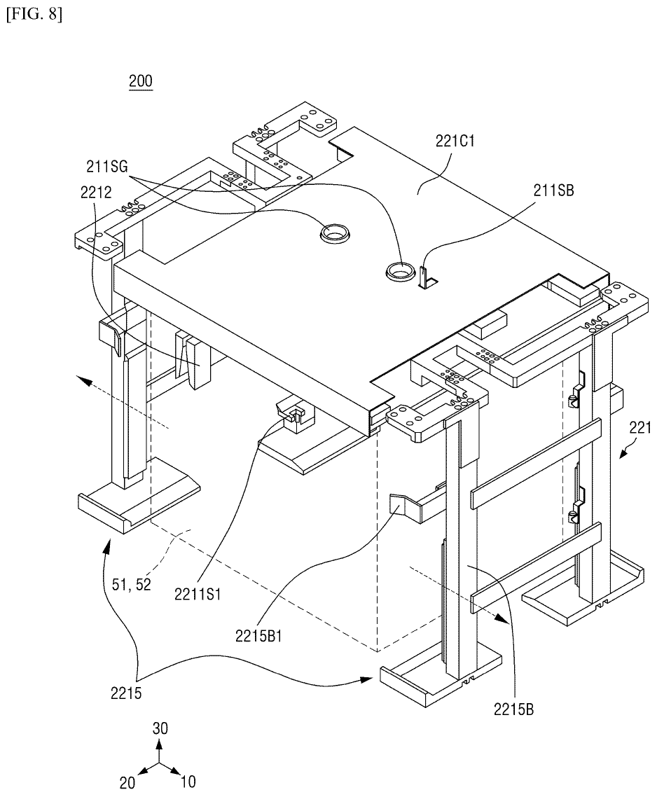

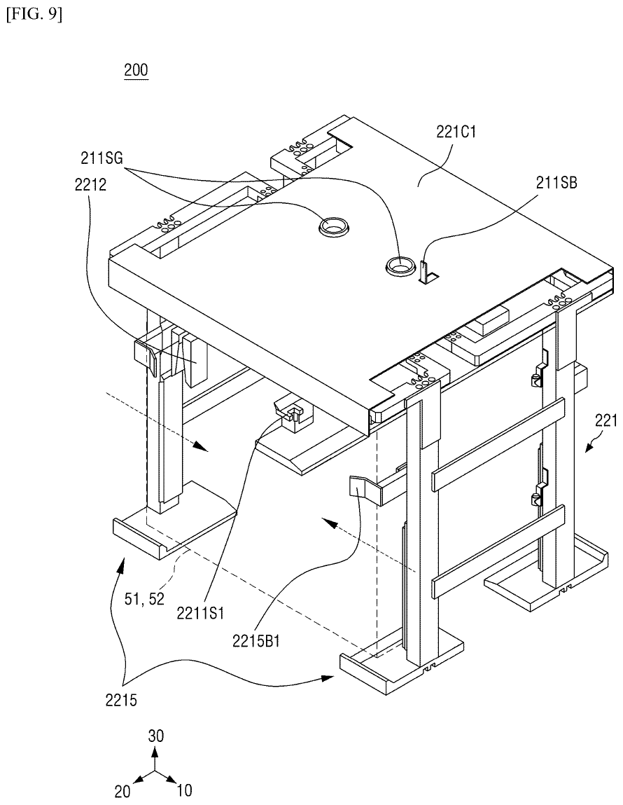

FIG. 4 is a front view illustrating a state where a first hand module of a gripping device is raised in the transport apparatus according to some embodiments of the present disclosure, FIG. 5 is a front view illustrating a state where the first hand module of the gripping device is lowered in the transport apparatus according to some embodiments of the present disclosure, and FIG. 6 is a front view illustrating a state where the first hand module of the gripping device grips items to be transported in the transport apparatus according to some embodiments of the present disclosure. FIG. 7 is a perspective view illustrating a first hand module of a gripping device according to a first embodiment of the present disclosure, FIG. 8 is a perspective view illustrating a state where the spacing in the first hand module of the gripping device according to the first embodiment of the present disclosure is widened, and FIG. 9 is a perspective view illustrating a state where the spacing in the first hand module of the gripping device according to the first embodiment of the present disclosure is narrowed so that the first hand module contacts the items to be transported.

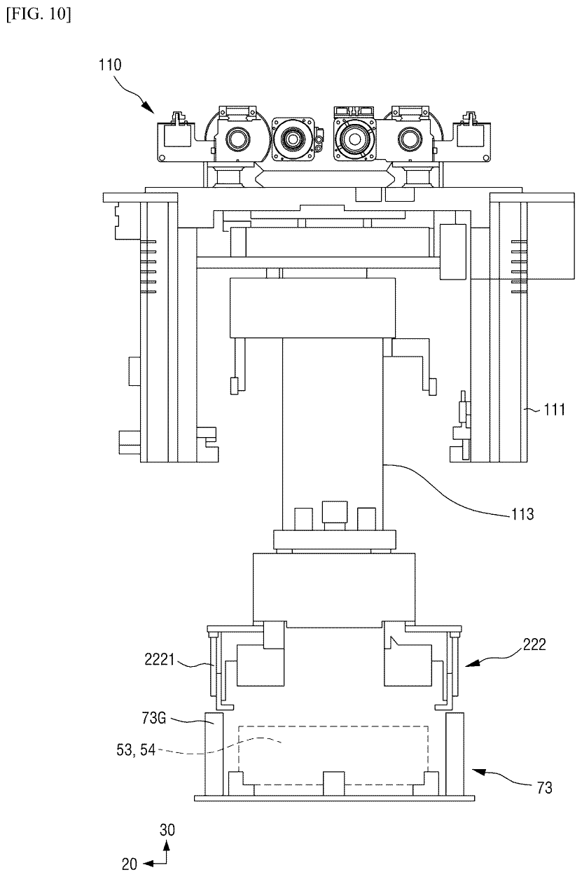

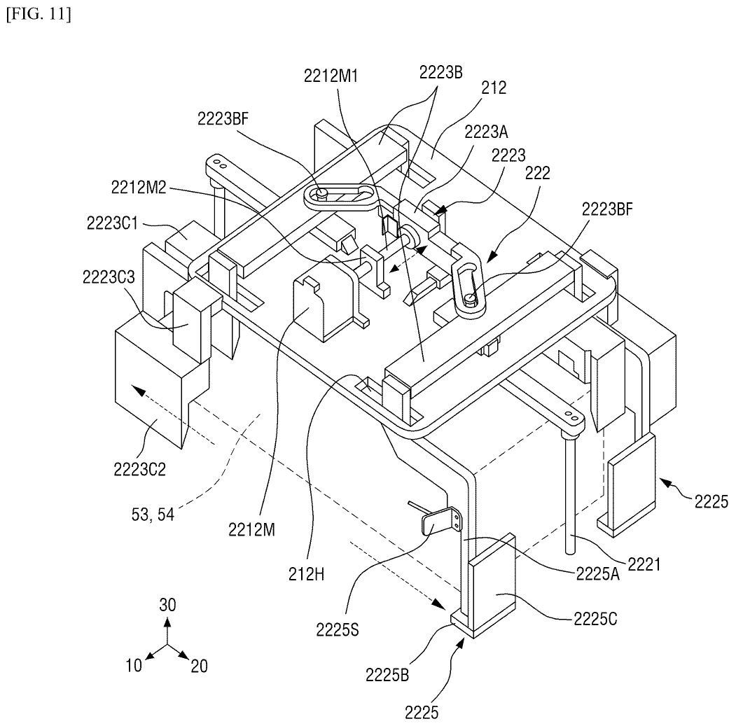

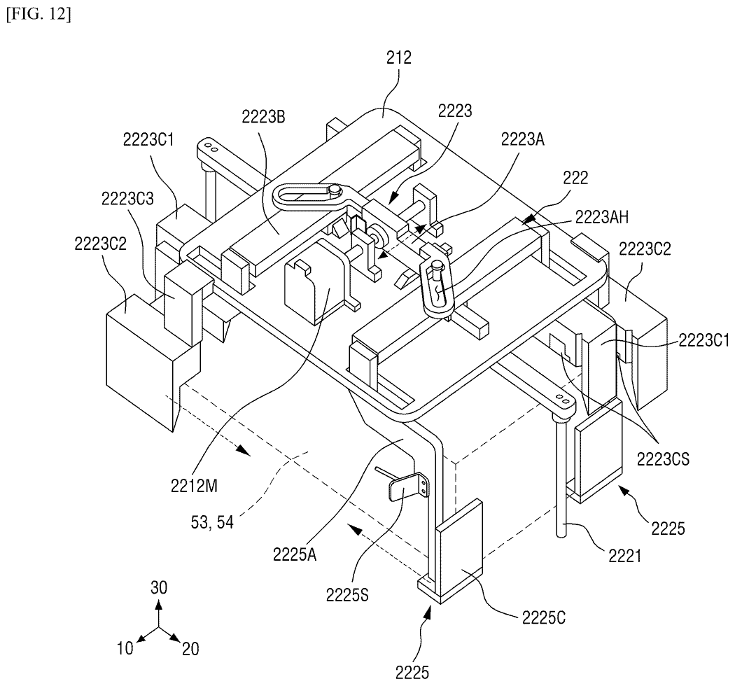

FIG. 10 is a front view illustrating a second hand module of the gripping device according to some embodiments of the present disclosure, FIG. 11 is a perspective view a state where the spacing in a second hand module of the gripping device according to the first embodiment of the present disclosure is widened, and FIG. 12 is a perspective view illustrating a state where the spacing in the second hand module of the gripping device with according to the first embodiment of the present disclosure is narrowed to grip the items to be transported.

Referring to FIGS. 4 through 12, the transport apparatus 100 may include a vehicle 110 and a gripping device 200.

The vehicle 110 may transport items 50 to be transported within a semiconductor manufacturing plant. The vehicle 110 may be provided with a housing 111 and a belt 113. The housing 111 may have a structure with an open bottom and open sides.

The housing 111 may be provided with an insert 111A, which is inserted into cylindrical guiders 211SG of the gripping device 200, and a housing sensor 111B, which allows a second sensor bar 211SB of the gripping device 200 to pass through to detect whether the gripping device 200 has been raised or lowered. The belt 113 may adjust the height of the gripping device 200 based on the degree of winding.

The gripping device 200 may be connected to the vehicle 110 and may grip the items 50. For example, the gripping device 200 may include a base unit (211 and 212) and a hand unit (221 and 222).

The base unit (211 and 212) may be provided to be vertically movable within the vehicle 110. The base unit (211 and 212) may be connected to the belt 113 of the vehicle 110, and the height of the base unit (211 and 212) may be adjusted through the adjustment of the length of the belt 113. The base unit (211 and 212) may be plate-shaped, and the hand unit (221 and 222) may be installed on the base unit (211 and 212).

The hand unit (221 and 222) may include a first hand module 221 and a second hand module 222. The first hand module 221 may be installed on the first plate 211, and the second hand module 222 may be installed on the second plate 212.

The base unit (211 and 212) may be provided with cylindrical guiders 211SG and the second sensor bar 211SB. The cylindrical guiders 211SG may accommodate the insert 111A and/or the belt 113 installed in the housing 111. The second sensor bar 211SB may cross the housing sensor 111B of the housing 111, blocking the reflection of laser light to detect the raised or lowered state of the hand unit (221 and 222). For example, if the housing sensor 111B of the housing 111 detects the second sensor bar 211SB, the raising or lowering of the hand unit (221 and 222) may be terminated.

The hand unit (221 and 222) may be provided on the base unit (211 and 212) and may have an adjustable spacing to either grip or release the items 50. Here, the spacing may refer to the width of the items 50 that are seated in the hand unit (221 and 222).

The hand unit (221 and 222) may grip the items 50 with four or more specifications. For example, the hand unit (221 and 222) may include a first hand module 221 and a second hand module 222.

The hand unit (221 and 222) may include motors (2211M and 212M), a conversion module (2213 and 2223), and grippers (2215 and 2225). A first hand module 221 may include first motors 2211M, first moving modules 2213, and a first pair of grippers 2215, and a second hand module 222 may include a second motor 2212M, a second moving module 2223, and a second pair of grippers 2225.

In other words, the motors (2211M and 2212M) may be divided into the first motors 2211M and the second motor 2212M. The designation of the first motors 2211M and the second motor 2212M is merely for the ease of understanding and explanation. The first motors 2211M and the second motor 2212M may both generate rotational force, causing first shafts 2211M1 and a second shaft 2212M1 to rotate similarly.

The conversion module (2213 and 2223) may convert the rotational motion of the motors (2211M and 2212M) into linear motion and may include the first moving modules 2213 and the second moving module 2223. The first moving modules 2213 may be provided in the first hand module 221, and the second moving module 2223 may be provided in the second hand module 222.

The grippers (2215 and 2225) may be connected to the conversion module (2213 and 2223), and the spacing between the grippers (2215 and 2225) may be adjusted in conjunction with the conversion module (2213 and 2223). For example, the first grippers 2215 may be provided in the first hand module 221, and the second grippers 2225 may be provided in the second hand module 222.

Referring to FIGS. 4 through 9, the first hand module 221 may grip the first target items 51 and 52. The first hand module 221 includes a first sensor 2211S1, which detects the first sensor bar 71B of the first stand 71 that operates similarly to the housing sensor 111B, and first couplings 2212, where the protrusions 71P fit, and may be provided with a cover 221C1.

The first hand module 221 drives the first moving modules 2213 via the operation of the first motors 2211M. The first moving modules 2213 may be provided to be movable in a first direction 10, allowing the first grippers 2215 to contact or separate from the first target items 51 and 52, which are the items 50 to be transported, thus enabling the first grippers 2215 to grip or release the first target items 51 and 52.

For example, each of the first motors 2211M includes a first shaft 2211M1 with a first thread (not illustrated) formed on its outer circumferential surface, and a first bracket 2211M2, which allows the first shaft 2211M1 to be rotatable and is fixed to the first plate 211.

A pair of first motors 2211M may be provided to allow a pair of first moving modules 2213 to either approach or separate.

A first through hole (not illustrated) with a second thread (not illustrated) on its inner circumferential surface, which engages with the first thread of the corresponding first motor 2211M, may be formed in the corresponding first moving module 2213. Both ends of each of the first moving modules 2213 may be slidably connected to the first plate 211.

For example, each of the first moving modules 2213 may include linear motion (LM) guiders 2213A, first moving blocks 2213B, and a first connecting block 2213C.

The LM guiders 2213A may be fixed to the first plate 211 and may extend in the first direction 10, in which the first grippers 2215 approaches or separates from the items 50, guiding the movement of the first moving blocks 2213B along the first direction 10.

The first moving blocks 2213B may be slidably provided on the LM guiders 2213A. The first moving blocks 2213B and the LM guiders 2213A may be implemented as slidable structures such as rails and/or ball bearings to enable sliding, but the present disclosure is not limited thereto.

The first connecting block 2213C may be provided with the first moving blocks 2213B at both ends, and a first through hole may be formed in the first connecting block 2213C to connect with the corresponding first motor 2211M. The first connecting block 2213C may be bent toward the corresponding first motor 2211M to ensure that the first shaft 2211M1 of the corresponding first motor 2211M does not protrude beyond the corresponding first gripper 2215.

The first grippers 2215 may be connected to the first moving modules 2213. The first grippers 2215 may include first support plates 2215A and support bars 2215B. The first support plates 2215A may extend at the bottoms of the first grippers 2215 in the first direction 10 to accommodate the items 50. The bottom surfaces of the first support plates 2215A may be sloped, allowing easy insertion of the lower surfaces of the items 50. Ends of the first support plates 2215A, corresponding to (or positioned at) the corners of the items 50, may extend upwardly to secure the corners of the items 50.

The first support plates 2215A may be connected to the lower ends of the support bars 2215B, and the first moving modules 2213 may be connected to the upper ends of the support bars 2215B. That is, the support bars 2215B may serve as intermediaries between the first moving modules 2213 and the first support plates 2215A.

Two pairs of support bars 2215B may be provided at either side of the first target items 51 and 52, but the present disclosure is not limited thereto. Each of the pairs of support bars 2215B may be provided with a transported item guider 2215B1, whose width gradually increases toward the items 50. The transported object guider 2215B1 may extend on both sides of each of the pairs of support bars 2215B and may be formed with diverging ends to avoid contact with the edges or sides of the items 50 (see FIG. 7).

Additionally, the support bars 2215B may be provided with second sensors 2211S2 for detecting the items 50. A plurality of second sensors 2211S2 may be provided to be vertically spaced apart from one another. For example, the second sensors 2211S2 may be push sensors positioned at the heights of the first and second specifications of the items 50, i.e., the heights of the first target items 51 and 52.

Referring to FIGS. 10 through 12, the second hand module 222 may grip the second target items 53 and 54. The second hand module 222 includes second couplings 2221, which are inserted into the fitting grooves of the coupling guiders 73G provided on the second stand 73. The second hand module 222 operates via the second moving module 2223, driven

by the second motor 2212M.

The second motor 2212M, which drives the second moving module 2223, includes the second shaft 2212M1 with a third thread (not illustrated) formed on its outer circumferential surface, and a second bracket 2212M2, which secures the second shaft 2212M1 for rotation and is fixed to the second plate 212.

The second moving module 2223 allow the second grippers 2225 to move in the first direction 10, which is perpendicular to a second direction 20, enabling the second grippers 2225 to contact or separate from the second target items 53 and 54, which are the items 50 to be transported. Accordingly, the second grippers 2225 can grip or release the second target items 53 and 54.

For example, the second moving module 2223 may include a second connecting block 2223A, second moving blocks 2223B, and fixed blocks (2223C1, 2223C2, and 2223C3).

The second connecting block 2223A may receive rotational force from the second motor 2212M and may thus move rectilinearly. The second connecting block 2223A may be penetrated by the second shaft 2212M1 of the second motor 2212M, and may bar-shaped, extending perpendicularly to the second shaft 2212M1. A second through hole (not illustrated) with a fourth thread formed on its inner circumferential surface to engage the third thread of the second shaft 2212M1, may be formed at the center of the second connecting block 2223A.

Both ends of the second connecting block 2223A are angled at either an acute or obtuse angle relative to the second direction 20. Guide holes 2223AH may be formed at both ends of the second connecting block 2223A. The guide holes 2223AH may guide the path of cam followers 2223BF.

A pair of second moving blocks 2223B may be provided, and the spacing between the second moving blocks 2223B may be adjusted in conjunction with the second connecting block 2223A. The second moving blocks 2223B includes the cam followers 2223BF, which slide or pull along the guide holes 2223AH. The second moving blocks 2223B may be bar-shaped, and the second grippers 2225 may be fixed to at both ends of the second moving blocks 2223B.

The fixed blocks (2223C1, 2223C2, and 2223C3) may be connected to the second plate 212 and may be provided with third sensors 2223CS, which are for detecting contact with the second target items 53 and 54. For example, the fixed blocks (2223C1, 2223C2, and 2223C3) may include first blocks 2223C1 and second blocks 2223C2. The first blocks 2223C1 may be connected to the second plate 212 and may contact the second target item 53 with third specification. The second blocks 2223C2 may be connected to the second plate 212 and may contact the second target item 54. The second blocks 2223C2 may include connectors 2223C3, which are connected to the second plate 212, and may be connected to the second plate 212 through the connectors 2223C3, but the present disclosure is not limited thereto.

The second grippers 2225 may be connected to the second moving module 2223. The second grippers 2225 may pass through the second plate 212. For example, insertion holes 212H may be formed in the second plate 212, and thus, the second grippers 2225 may be connected to both ends of the second moving module 2223 through the insertion holes 212H. For example, the second grippers 2225 may include first bars 2225A, second support plates 2225B, third support plates 2225C, and sensors 2225S.

Each of the first bars 2225A may have a bent surface (not illustrated) opposing the circumferential surfaces of the second target items 53 and 54 in the first direction 10 and an extension surface (not illustrated) extending downwardly from the bent surface. The second support plates 2225B may be provided below the first bars 2225A and may extend toward the second target items 53 and 54 to support the items 50. The third support plates 2225C may extend in a different direction from the bent surfaces of the first bars 2225A to oppose the circumferential surfaces of the items 50. In other words, the first bars 2225A, the second support plates 2225B, and the third support plates 2225C may be arranged to oppose and secure the peripheries and lower surfaces of the second target items 53 and 54, preventing their escape.

The sensors 2225S may detect the second target items 53 and 54, thereby determining whether the second target items 53 and 54 are accommodated in the second hand module 222. For example, the second target items 53 and 54 may be provided with reflectors (e.g., retroreflective stickers), and the sensors 2225S may emit laser light and detect any laser light reflected from the reflectors to determine if the second target items 53 and 54 are accommodated in the second hand module 222.

Although the embodiments of the present invention have been described above with reference to the accompanying drawings, it will be understood by those skilled in the art that various modifications and changes can be made without departing from the spirit or essential characteristics of the present invention. Therefore, the above-described embodiments should be considered in all respects as illustrative and not restrictive.

What is claimed is:

1. A gripping device connected to a vehicle for transporting items to be transported in a semiconductor manufacturing plant, comprising:
a base unit provided on the vehicle to be movable up and down; and
a hand unit provided on the base unit and having an adjustable spacing to either secure or release the items,
wherein the hand unit includes: motors; a conversion module converting the rotational motion of the motors into linear motion; and grippers connected to the conversion module, with their spacing adjusted in conjunction with the conversion module.

2. The gripping device of claim 1, wherein
the items include first target items having first and second specifications and second target items having third and fourth specifications, and
the hand unit includes a first hand module for gripping or releasing the first target items, and a second hand module for gripping or releasing the second target items.

3. The gripping device of claim 2, wherein:
the first target items are supported on a first stand,
the first stand is provided with first protrusions, and
the first hand module includes first couplings that the first protrusions fit into, and a first sensor for detecting the first stand.

4. The gripping device of claim 2, wherein:
the second target items are supported on a second stand,
the second stand is provided with coupling guiders having fitting grooves formed therein, and
the second hand module includes second couplings inserted into the fitting grooves.

5. The gripping device of claim 2, wherein
the first target items and the second target items differ in at least one of size and weight,
each of the first and second specifications is provided in the form of a box with a combined width, length, and height of 1000 mm and 1500 mm, and
each of the third and fourth specifications is provided in the form of a box with a combined width, length, and height of 300 mm and 1000 mm.

6. The gripping device of claim 1, wherein
the base unit includes a first plate,
the motors include a first motor,
the conversion module includes a first moving module provided to be movable within the base unit,
the grippers include a pair of first grippers connected to the first moving module,
the first motor is provided with a first shaft with a first thread formed on its outer circumferential surface,
a first through hole with a second thread formed on its inner circumferential surface is formed in the first moving module, and
an end of the first moving module is slidably connected to the first plate.

7. The gripping device of claim 6, wherein the first grippers include, at their bottoms, first support plates extending downwardly toward the items to contact lower surfaces of the items.

8. The gripping device of claim 6, wherein the first moving module includes: linear motion (LM) guiders provided on the first plate and extending in a direction where the first grippers approach or separate from the items; and first moving blocks provided to be slidable on the LM guiders.

9. The gripping device of claim 8, wherein the first moving module further includes a first connecting block that is provided with the first moving blocks at both ends, has the first through hole formed therein, and is bent toward the first motor.

10. The gripping device of claim 6, wherein the first motor includes a first bracket that allows the first shaft to be rotatable and is fixed to the first plate.

11. The gripping device of claim 1, wherein
the base unit includes a second plate,
the motors include a second motor provided with a second shaft with a third thread formed on its outer circumferential surface,
the conversion module includes a second moving module moving to grip or release the items,
the grippers include a pair of second grippers connected to the second moving module, and
the second moving module includes:
a second connecting block having, formed at its center, a second through hole with a fourth thread engaging the third thread, moving linearly by receiving rotational force from the second motor, and bent at both ends at an acute or obtuse angle with guide holes formed therein; and
a pair of second moving blocks including cam followers that slide or pull along the guide holes, and whose spacing is adjustable in conjunction with the second connecting block.

12. The gripping device of claim 11, wherein the second grippers includes: first bars having bent surfaces that oppose circumferential surfaces of the items and extension surfaces that extend downwardly from the bent surfaces; second support plates provided at lower ends of the first bars and extending toward the items to support lower surfaces of the items; and third support plates extending in a different direction from the bent surfaces of the first bars to oppose the circumferential surfaces of the items.

13. The gripping device of claim 12, wherein the hand unit further includes fixed blocks, which are connected to the second plate and are provided with third sensors for detecting contact with the items.

14. The gripping device of claim 13, wherein the fixed blocks include: first blocks, which are connected to the second plate and contact the items with a third specification; and
second blocks, which are connected to the second plate and contact the items with a fourth specification different from the third specification, and are provided with connectors connecting the second blocks to the second plate.

15. A transport apparatus comprising:
a vehicle for transporting items to be transported in a semiconductor manufacturing plant; and
the gripping device of claim 1.

16. A transport apparatus comprising:
multiple vehicles for transporting box-shaped items to be transported in a semiconductor manufacturing plant, the items including first target items, which are supported on a first stand and have first and second specifications, and second target items, which are supported on a second stand and have third and fourth specifications that are different from the first and second specifications;
a base unit provided on the vehicles to be movable up and down, the base unit including a first plate, which is connected to one of the vehicles, and a second plate, which is connected to another one of the vehicles; and
a hand unit for gripping or releasing the items, the hand unit provided on the base unit and having an adjustable spacing to either secure or release the items,
wherein
the hand unit includes:
a first hand module for gripping or releasing the first target items, which includes first couplings into which the first protrusions fit, and a first sensor for detecting the first stand; and
a second hand module for gripping or releasing the second target items, which includes second couplings that fit into the coupling grooves, the first hand module includes:
a first motor including a first shaft having a first thread formed on its outer circumferential surface, and a first bracket that allows the first shaft to be rotatable and is fixed to the first plate;
a first moving module including linear motion (LM) guiders provided on the first plate, first moving blocks provided to be slidable on the LM guiders, and a first connecting block provided with the first moving blocks at both ends and having a first through hole formed with a second thread on its inner circumferential surface that engages with the first thread, and bent toward the first motor; and
a pair of first grippers connected to the first moving module and provided at its bottom with first support plates, which extend downwardly toward the first target items to contact lower surfaces of the first target items, and the second hand module includes:
a second motor provided with a second shaft with a third thread formed on its outer circumferential surface;
a second moving module including a second connecting block, which has a second through hole formed with a fourth thread engaging the third thread, moves linearly by receiving rotational force from the second motor, and is bent at both ends at an acute or obtuse angle with guide holes formed therein, and a pair of second moving blocks including cam followers that slide or pull along the guide holes, and whose spacing is adjustable in conjunction with the second connecting block;
a pair of second grippers connected to the second moving module and including first bars having bent surfaces that oppose circumferential surfaces of the second target items and extension surfaces that extend downwardly from the bent surfaces, second support plates provided at lower ends of the first bars and extend toward the second target items to support lower surfaces of the second target items, and third support plates extending in a different direction from the bent surfaces of the first bars to oppose the circumferential surfaces of the second target items; and
fixed blocks including first blocks connected to the second plate and contacting the second target items with the third specification, second blocks connected to the second plate and contacting the second target items with the fourth specification, and third sensors for detecting contact with the second target items.
